(19) United States
(12) Patent Application Publication
(10) Pub. No.: US 2023/0187534 A1
(43) Pub. Date: Jun. 15, 2023

(54) SEMICONDUCTOR DEVICE AND METHOD FOR MANUFACTURING SAME

(71) Applicant: DB HiTek Co., Ltd., Bucheon-si (KR)

(72) Inventor: Dong Hoon PARK, Uiwang-si (KR)

(21) Appl. No.: 18/073,544

(22) Filed: Dec. 1, 2022

(30) Foreign Application Priority Data
Dec. 15, 2021 (KR) 10-2021-0179472

(51) Int. Cl. H01L 29/66; H01L 29/06

(52) U.S. Cl. CPC H01L 29/66545; H01L 29/0649

(57) ABSTRACT

Provided is a semiconductor device and, more particularly, to a semiconductor device including a dummy gate and a dummy structure passing through the dummy gate, adjacent to an isolation region including a DTI region, so that the pattern density (e.g., of the gates and/or DTI regions across the device) is more uniform, thereby improving the uniformity of structures made in subsequent processes such as planarization (e.g., chemical mechanical polishing) and/or etching, and compensating for potential weaknesses or sources of defects in such processes.

### CROSS REFERENCE TO RELATED APPLICATION

The present application claims priority to Korean Patent Application No. 10-2021-0179472, filed Dec. 15, 2021, the entire contents of which are incorporated herein for all purposes by this reference.

### BACKGROUND OF THE INVENTION

### Field of the Invention

The present disclosure relates to a semiconductor device and, more particularly, to a semiconductor device in which a dummy gate and a dummy structure passing through the dummy gate are adjacent to an isolation region including a DTI region, so that the pattern density (e.g., of the gates and/or DTI regions across the device) is more uniform, thereby improving the uniformity of structures formed in subsequent processes such as planarization (e.g., chemical mechanical polishing [CMP]) and/or etching, and compensating for potential weaknesses or sources of defects in such processes.

### Description of the Related Art

In recent bipolar-CMOS-DMOS (BCD) semiconductor manufacturing processes, it is desirable to achieve a breakdown voltage of 100V or more (e.g., for the DMOS transistors). According to this target breakdown voltage, a deep trench isolation (DTI) region can reduce or minimize leakage current by electrically isolating adjacent devices.

FIG. 1 is a cross-sectional view for reference showing a DTI region in a conventional semiconductor device.

Referring to FIG. 1, a DTI region 910 used for electrical isolation between adjacent devices includes a trench region formed by etching a substrate 901 to a predetermined depth in a single etching process, then filling the resulting trench with an insulating material. When the DTI region 910 is formed by a single etching process as described above, there may be technical limitations in forming the deep trench. That is, when the DTI region is formed by etching the substrate 901 in a single process, it is not easy to form the trench sufficiently deep to electrically isolate that adjacent devices. When the trench is not sufficiently deep to achieve a breakdown voltage (BV) of 100V or more, the breakdown voltage characteristics may deteriorate due to an increase in the electric field area of the region of the substrate 901 below the DTI region 910 and an increase in the leakage current. In addition, as the separation distance between transistor devices increases in order to reduce or prevent transmission of noise between the adjacent devices, the overall chip size inevitably increases.

Moreover, in general, when using a DTI region, since the pattern density for the DTI region is very low, problems such as poor deposition uniformity and over-etching in subsequent processes including deposition and etching of an interlayer dielectric 180 arise due to variations in the DTI pattern density across the device, resulting in process reliability degradation.

To solve the above-mentioned problems, the present disclosure concerns a novel semiconductor device having an improved structure and a method of manufacturing the same, described below.

### Document of Related Art

Korean Patent Application Publication No. 10-2003-0000592, entitled “METHOD OF MANUFACTURING SEMICONDUCTOR DEVICE WITH STI/DTI STRUCTURE.”

### SUMMARY OF THE INVENTION

The present disclosure has been made to solve the problems of the related art, and an objective of the present disclosure is to provide a semiconductor device and a method of manufacturing the same that improve isolation characteristics between adjacent devices, thereby improving device characteristics and reducing chip size by extending an isolation region to relatively deep in a substrate by separately forming a first trench having a relatively large width (e.g., a “pre-DTI region”) and a second trench having a relatively narrow width (i.e., the deep trench isolation [DTI] region). The second trench may overlap completely with the first trench.

In addition, an objective of the present disclosure is to provide a semiconductor device and a method of manufacturing the same that improve uniformity of structures made in subsequent processes and compensating for potential weaknesses or sources of defects in such processes by making the pattern density (e.g., of the gates and/or DTI regions across the device) more uniform by forming a dummy gate and a dummy structure penetrating or passing through the dummy gate (e.g., adjacent to the isolation region).

Moreover, an objective of the present disclosure is to provide a semiconductor device and a method of manufacturing the same that reduce or prevent deterioration of characteristics of the isolation region by covering the isolation region with an additional insulating layer, to prevent a contact material such as tungsten from remaining on the isolation region during subsequent processing (e.g., for forming a contact).

Furthermore, an objective of the present disclosure is to provide a semiconductor device and a method of manufacturing the same that facilitate subsequent processing by removing a step height at the boundary between an interlayer dielectric and an isolation region by planarization (e.g., CMP) of an additional insulating layer on the interlayer dielectric, optionally after removing an etch stop layer on the interlayer dielectric.

According to one or more embodiments of the present disclosure, there is provided a semiconductor device including a substrate; a gate on the substrate; a dummy gate on the substrate; an interlayer dielectric on the substrate; an isolation layer in the substrate; an isolation region passing through the interlayer dielectric and the first isolation layer, and penetrating into the substrate; and a dummy structure passing through the interlayer dielectric and extending to and/or passing through the dummy gate.

According to one or more other embodiments of the present disclosure, in the semiconductor device of the present disclosure, the isolation region may have a lowermost surface deeper than a lowermost surface of the dummy structure.

According to one or more other or further embodiments of the present disclosure, in the semiconductor device of the present disclosure, the isolation region may include a pre-deep trench isolation (DTI) region passing through the interlayer dielectric and extending at least partially through the first isolation layer; and a DTI region connected to the pre-DTI region and extending a predetermined distance into the substrate, and having a width smaller than that of the pre-DTI region.

According to one or more other or further embodiments of the present disclosure, in the semiconductor device of the present disclosure, the dummy structure may have a lowermost surface that is below a lowermost surface of the dummy gate.

ording to one or more other or further embodiments of the present disclosure, the semiconductor device of the present disclosure may further include an air gap in the isolation region.

According to one or more embodiments of the present disclosure, there is provided a semiconductor device of the present disclosure that may include a substrate; a first buried layer having a second conductivity type in the substrate; a deep well directly or indirectly connected to the first buried layer; a first well in the deep well; a drain in the first well and at a surface of the substrate; a body region having a first conductivity type in the substrate; a source in the body region and at the surface of the substrate; a gate on the substrate; a dummy gate on the substrate; an interlayer dielectric covering the gate (and, optionally, at least part of the dummy gate); an isolation layer in the substrate; an isolation region extending into the substrate through the isolation layer; a dummy structure extending at least partially through the dummy gate; and an air gap in the isolation region.

According to one or more other or further embodiments of the present disclosure, in the semiconductor device of the present disclosure, the isolation region and the dummy structure may penetrate or pass through the interlayer dielectric.

According to one or more other or further embodiments of the present disclosure, the semiconductor device of the present disclosure may further include a high-voltage well having the second conductivity type, connected to the first buried layer and the deep well; and a second buried layer having the first conductivity type in the substrate.

According to one or more other or further embodiments of the present disclosure, in the semiconductor device of the present disclosure, the isolation region may include a pre-DTI region passing through the interlayer dielectric and extending at least partially through the isolation layer; and a DTI region connected to the pre-DTI region and extending a predetermined distance into the substrate, and having a width smaller than that of the pre-DTI region. The air gap may have an uppermost end or surface in or below the DTI region.

According to one or more other or further embodiments of the present disclosure, the semiconductor device of the present disclosure may further include a non-salicide structure on the dummy gate.

According to one or more embodiments of the present disclosure, a method of manufacturing a semiconductor device includes forming an isolation layer in a substrate; forming a gate on the substrate; forming a dummy gate on the substrate (optionally simultaneously with or at the same time as the gate); depositing an interlayer dielectric on the substrate; forming a first trench by etching the interlayer dielectric (e.g., on or over the isolation layer) and the isolation layer; forming a second trench by etching the substrate under the isolation layer or exposed by the first trench; forming a third trench by etching the interlayer dielectric (e.g., on or over the dummy gate) and the dummy gate; and filling the first trench, the second trench, and the third trench with an insulating layer to form an isolation region (e.g., in the first and second trenches) and a dummy structure (e.g., in the third trench).

According to one or more other embodiments of the present disclosure, in the method of manufacturing a semiconductor device of the present disclosure, the second trench and the third trench may be formed in a single process (e.g., at the same time), and the second trench may have a lowermost surface that is below a lowermost surface of the third trench.

According to one or more other or further embodiments of the present disclosure, the method of manufacturing a semiconductor device of the present disclosure may further include depositing an etch stop layer on the interlayer dielectric, and forming the isolation region and the dummy structure may include depositing a first insulating layer in the first trench and the second trench; removing the first insulating layer on or above the etch stop layer and at least partially from the second trench (and, optionally, at least partially from the first trench to leave a first insulating liner along sidewalls of the first and second trenches); and depositing a second insulating layer in the first trench, the second trench, and the third trench.

According to one or more other or further embodiments of the present disclosure, the method of manufacturing a semiconductor device of the present disclosure may further include removing the etch stop layer; depositing a third insulating layer on the interlayer dielectric (e.g., directly on the interlayer dielectric) and the isolation region (e.g., a pre-DTI region of the isolation region); and planarizing the third insulating layer.

According to one or more other or further embodiments of the present disclosure, in the method of manufacturing a semiconductor device of the present disclosure, forming the first trench may include forming a first photoresist pattern having an opening exposing the etch stop layer (e.g., in an area corresponding to the first trench); and etching the etch stop layer, the interlayer dielectric, and the isolation region.

According to one or more other or further embodiments of the present disclosure, in the method of manufacturing a semiconductor device of the present disclosure, forming the second trench may include forming a second photoresist pattern on the etch stop layer and along sidewalls of the first trench; and etching the substrate under or exposed by the first trench.

According to one or more other or further embodiments of the present disclosure, a method of manufacturing a semiconductor device of the present disclosure may include forming an isolation layer in a substrate; forming a gate on the substrate; forming a dummy gate on the substrate; depositing an interlayer dielectric on the substrate; forming a pre-DTI region extending at least partially through the isolation layer; forming a DTI region extending below the pre-DTI region, the DTI region including an air gap and having a width smaller than that of the pre-DTI region; and forming a dummy structure extending at least partially through the dummy gate.

According to one or more other or further embodiments of the present disclosure, the method of manufacturing a semiconductor device of the present disclosure may further include forming a non-salicide structure on the dummy gate.

According to one or more other or further embodiments of the present disclosure, in the method of manufacturing a semiconductor device of the present disclosure, forming the pre-DTI region and forming the DTI region may comprise two or more insulating layer depositions and etching (e.g., anisotropic etching) processes.

The present disclosure has the following effects by the above configurations.

The present disclosure can improve isolation characteristics between adjacent devices (e.g., between a DMOS transistor and an adjacent [and optionally bipolar or CMOS] transistor), thereby improving device characteristics and reducing chip size by including a relatively deep isolation region in a substrate, comprising a pre-DTI region in a first trench having a relatively large width and a separate DTI region in a second trench having a relatively narrow width.

In addition, the present disclosure can improve uniformity of structures made in subsequent processes and compensate for potential weaknesses or sources of defects in such processes by making the pattern density (e.g., of the gates and/or DTI regions across the device) more uniform by forming a dummy gate and a dummy structure penetrating or passing through the dummy gate, adjacent to the isolation region.

Moreover, the present disclosure can maintain (or reduce or prevent deterioration of) characteristics of the isolation region by covering the isolation region with an additional insulating layer to prevent a contact material such as tungsten from remaining on the isolation region during a subsequent contact-forming process.

Furthermore, the present disclosure can facilitate subsequent processing by removing a step height at the boundary between the interlayer dielectric and the isolation region by planarizing an additional insulating layer on the interlayer dielectric (e.g., after removing an etch stop or polishing stop layer from the interlayer dielectric and depositing the additional insulating layer).

Meanwhile, it should be added that even if effects not explicitly mentioned herein, the effects described in the following specification expected by the technical features of the present disclosure and their potential effects are treated as if they were described in the present disclosure.

### BRIEF DESCRIPTION OF THE DRAWINGS

The above and other objectives, features, and other advantages of the present disclosure will be more clearly understood from the following detailed description when taken in conjunction with the accompanying drawings, in which:

FIG. 1 is a cross-sectional view for reference showing a DTI region in a conventional semiconductor device;

FIG. 2 is a cross-sectional view of a semiconductor device according to one or more embodiments of the present disclosure;

FIG. 3 is a reference view showing the isolation characteristics according to the formation depth of the DTI region;

FIGS. 4 to 12 are cross-sectional views showing a method of manufacturing a semiconductor device according to one or more embodiments of the present disclosure; and

FIGS. 13 and 14 are cross-sectional views showing a process of removing a step height at the boundary between an isolation region and an interlayer dielectric.

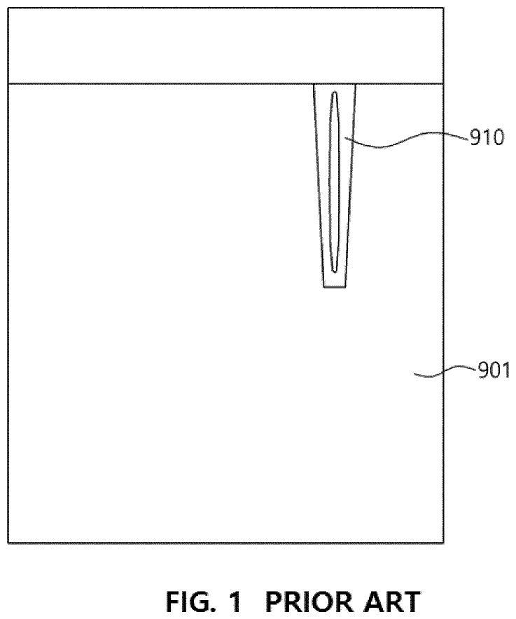

### DETAILED DESCRIPTION OF THE INVENTION

Hereinafter, embodiments of the present disclosure will be described in more detail with reference to the accompanying drawings. Embodiments of the present disclosure may be modified in various forms, and the scope of the present disclosure should not be construed as being limited to the following embodiments, but should be construed based on the matters described in the claims. In addition, these embodiments are provided for reference in order to more completely explain the present disclosure to those of ordinary skill in the art.

Hereinafter, it should be noted that when one component (or layer) is described as being on another component (or layer), one component may be directly on another component, or one or more further component(s) or layer(s) may be between the one component and the other component. In addition, when one component is expressed as being directly on or above another component, no other component(s) are between the components. Moreover, being “on top”, “above”, “below”, “on”, “under” or “on one (a first) side” or “on opposite sides” of a component means a relative positional relationship.

The terms first, second, third, etc. may be used to describe various items such as various components, regions and/or parts. However, the items are not limited by these terms.

In addition, it should be noted that, where certain embodiments are otherwise feasible, certain process sequences may be performed other than those described below. For example, two processes described in succession may be performed substantially simultaneously or in the reverse order.

The term “metal oxide semiconductor” (MOS) used below is a general term, and “M” is not limited to only metal, and may refer to various types of conductors. Also, “S” may be a substrate or a semiconductor structure, and “O” is not limited to oxide, and may include various types of organic or inorganic insulating materials.

Moreover, the conductivity type of a doped region or component may be defined as “p-type” or “n-type” according to the main carrier characteristics, but this is only for convenience of description, and the technical spirit of the present disclosure is not limited to what is illustrated. For example, hereinafter, “p-type” or “n-type” may be as replaced with the more general terms “first conductivity type” or “second conductivity type”, and here, the first conductivity type may refer to p-type, and the second conductivity type may refer to n-type.

Furthermore, it should be understood that “high concentration” and “low concentration” referring to the doping concentration of the impurity region mean the relative doping concentration of one component to one or more other components.

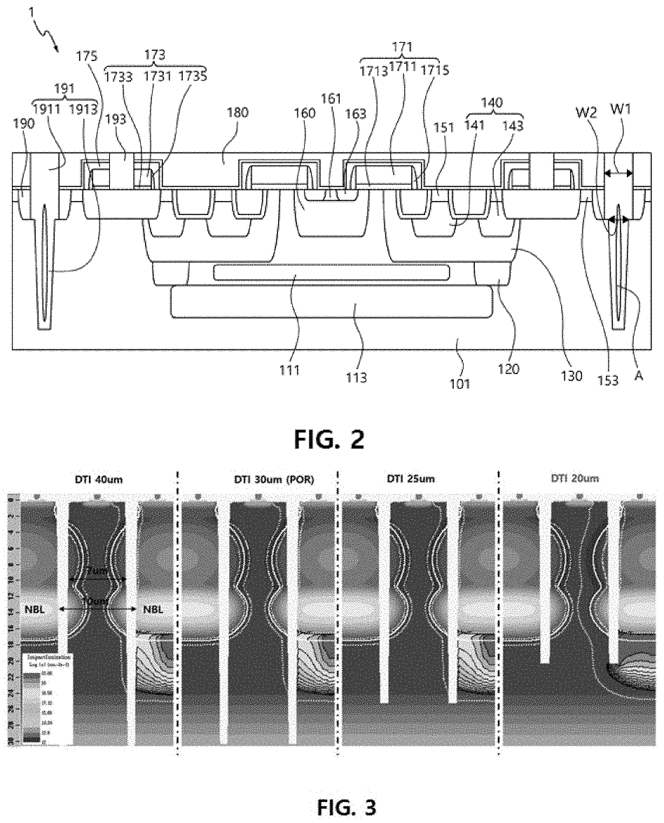

FIG. 2 is a cross-sectional view of a semiconductor device according to one or more embodiments of the present disclosure.

Hereinafter, a semiconductor device 1 according to one or more embodiments of the present disclosure will be described in detail with reference to the accompanying drawings.

Referring to FIG. 2, the present disclosure relates to the semiconductor device 1 and, more particularly, to the semiconductor device 1 including a dummy gate and a dummy structure passing through the dummy gate, adjacent to an isolation region including a DTI region, so that the pattern density (e.g., of the gates and/or DTI regions across the device) is more uniform, thereby improving the uniformity of structures made in subsequent processes such as planarization (e.g., CMP) and/or etching and compensating for potential weaknesses or sources of defects in such processes.

In addition, although in FIG. 2, a dummy structure is shown on opposite sides of buried layers 111 and 113 (to be described later), the dummy structures may be formed only on one side, and in some cases, on the other side of the buried layers 111 and 113, over an isolation region. There is no special limitation thereon.

In the semiconductor device 1 according to one or more embodiments of the present disclosure, a substrate 101 may comprise a well (not shown or identified) used as an active region on or in the substrate 101, and this active region may be defined by an isolation layer 190. The substrate 101 may comprise a single crystal (e.g., monolithic) silicon wafer doped with a first conductivity type dopant, a P-type diffusion region in such a wafer, or a P-type epitaxial layer epitaxially grown on the wafer. The isolation layer 190 may comprise a shallow trench isolation (STI) layer or structure, and may be formed by shallow trench isolation (STI), but is not limited thereto.

A first buried layer 111 and a second buried layer 113 may be in the substrate 101. For example, the first buried layer 111 may be above the second buried layer 113. In addition, a high-voltage well 120 may be connected to the second buried layer 113. The high-voltage well 120 comprises an ion implantation region L) having a second conductivity type, and may be in the substrate 101 and on the second buried layer 113. The aforementioned first buried layer 111 may comprise an impurity doped region having a first conductivity type, and the second buried layer 113 may comprise an impurity doped region having the second conductivity type. It should be noted that the first buried layer 111 and the high-voltage well 120 are not essential components of the present disclosure and may be omitted in some cases.

A deep well 130 may be in the substrate 101 and on the high-voltage well 120. The deep well 130 is connected (e.g., at one side) to the high-voltage well 120 and may comprise a second conductivity type impurity doped region (DNWELL). The deep well 130 may be directly connected to the second buried layer 113 in some cases.

In the deep well 130, for example, first and second well regions 141 and 143 (together, wells 140) having the second conductivity type are spaced apart (e.g., by an STI structure 190). A drain 151 may be in the first well 141, and a heavily doped region 153 may be in the second well 143. The drain 151 comprises an impurity doped region having the second conductivity type and includes a higher concentration of impurities than the first well 141. The heavily doped region 153 also comprises a doped region having the second conductivity type and includes a higher concentration of impurities than the second well 143.

The drain 151 and the heavily doped region 153 are preferably on or at the surface of the substrate 101. The above-described heavily doped region 153 functions as a guard ring together with the second well 143 and the high-voltage well 120 to reduce leakage current and improve safe operating area (SOA) conditions (e.g., of the corresponding DMOS transistor). The drain 151 may be electrically connected to a drain electrode, and the well 141 surrounding the drain 151 may further comprise a drain extension region that may improve breakdown voltage characteristics of the corresponding high voltage (e.g., DMOS) semiconductor device.

A body region 160 is in the substrate 101 between adjacent gates 170 of adjacent high voltage (e.g., DMOS) semiconductor devices. The body region 160 comprises a heavily doped region having the first conductivity type, and may be spaced apart from the deep well 130 (e.g., by channels [or portions thereof] of the adjacent high voltage semiconductor devices). A source 163 is in the body region 160 and on or at the surface of the substrate 101. The source 163 comprises a heavily doped region having the first conductivity type and may be electrically connected to a source electrode. In addition, a body contact 161 may be in the body region 160 and adjacent to or in contact with the source 163. The body contact 161 may comprise a heavily doped region having the first conductivity type.

Agate 171 and a dummy gate 173 may be on or above the substrate 101. First, the gate 171 may comprise a gate electrode 1711 between the drain 151 and the source 161. The gate electrode 1711 is on or over a channel region (not identified) of a corresponding high voltage semiconductor device, and the voltage applied to the gate electrode 1711 controls the conductivity of the channel region. The gate electrode 1711 may comprise, for example, conductive polysilicon, a metal, a conductive (e.g., refractory) metal nitride, and a conductive (e.g., refractory) metal silicide, or a combinations thereof, and may be formed by performing a chemical vapor deposition (CVD), physical vapor deposition (PVD, such as sputtering or evaporation), atomic layer deposition (ALD), metal-organic atomic layer deposition (MOALD), or metal-organic chemical vapor deposition (MOCVD) process, etc., but is not limited thereto.

A gate insulation film 1713 is between the gate electrode 1711 and the surface of the substrate 101, and the gate insulation film 1713 may comprise a silicon oxide layer (e.g., silicon dioxide), a high-k insulator layer (e.g., HfO2, hafnium silicate, ZrO₂, zirconium silicate, etc., which may or may not be nitrided), or a combination thereof. The gate insulation film 1713 may be formed by ALD, CVD, or PVD. A gate spacer 1715 may be on one or more sidewalls of the gate electrode 1711, and the gate spacer 1715 may comprise a nitride film (e.g., silicon nitride), an oxide film (e.g., silicon dioxide), or a combination thereof. A substantially identical gate spacer 1735 may also be on one or more sidewalls of the dummy gate 173 (described below).

A dummy gate 173 may be on the substrate 101, spaced apart from the gate 171. The dummy gate 173, like the gate 171, may comprise a dummy gate electrode 1731, a dummy gate insulation film 1733, and a dummy gate spacer 1735, substantially identical to the gate electrode 1711, the gate insulation film 1713, and the gate spacer 1715, and a detailed description thereof will be omitted. The dummy gate 173 is preferably on the isolation layer 190 (e.g., at the periphery of the DMOS transistor[s]).

A non-salicide (NSAL) region 175 may be between the dummy gate electrode 1731 and an interlayer dielectric 180 to be described later. The non-salicide region 175 generally comprises one or more insulator and/or dielectric materials, and may prevent or block formation of a salicide layer on the dummy gate 173. The non-salicide region 175 may also be on the dummy gate electrode 1711.

The interlayer dielectric 180 is on the substrate 101 and covers both the gate 171 and the dummy gate 173. The interlayer dielectric may comprise a relatively thin borophosphosilicate glass (BPSG) or phosphosilicate glass (PSG) film or liner, for example, and a relatively thick silicon oxide film. The silicon oxide may be deposited to a targeted thickness by CVD using tetraethyl orthosilicate (1E0S) as a precursor, and then the density of the silicon oxide film may be improved by rapid thermal annealing (RTA), but the scope of the present disclosure is not limited thereto.

The isolation layer 190, which may comprise an STI layer, has a predetermined depth (e.g., from the surface of the substrate 101). The isolation layer 190 may at least in part define the active region as described above, and may be formed, for example, by shallow trench isolation. In addition, an isolation region 191 may overlap the isolation layer 190. The isolation region 191 includes a DTI region 1913, and preferably overlaps the isolation layer 190 in order to maintain or maximize the area of the active region.

The isolation region 191 may include an upper pre-DTI region 1911 and a lower DTI region 1913. The pre-DTI region 1911 passes through the interlayer dielectric 180 and at least partially overlaps with the isolation layer 190. The lowermost surface of the pre-DTI region 1911 may be, for example, at a height substantially equal to or adjacent to the lowermost surface of the isolation layer 190.

In addition, it is preferable that the horizontal width of the pre-DTI region 1911 is narrower than the width of the isolation layer 190 or the width of the dummy gate 173. The DTI region 1913 is formed under the pre-DTI region 1911 to be connected to the lowermost surface of the pre-DTI region 1911. The DTI region 1913 may have sidewalls that are inclined or sloped, rather than straight (e.g., in the vertical direction). This is because the etching behavior of the substrate 101 with certain etchants (e.g., dry chemical and/or plasma-based etchants) may result in formation of sloped sidewalls in the trench. The DTI region 1913 has a width W2 that is smaller than the width W1 of the pre-DTI 1911. It is preferable that both the pre-DTI region 1911 and the DTI region 1913 comprise the same material as the interlayer dielectric 180. The DTI region 1913 generally isolates adjacent devices (e.g., transistors on opposite sides of the isolation region 191), and the pre-DTI region 1911 enables the DTI region 1913 to be sufficiently deep (e.g., as deep as possible) in the substrate 101.

An air gap A is in the isolation region 191. For example, the air gap A may below the DTI region 1913 or in the DTI region 1913, or may be in the pre-DTI region 1911. Preferably, the air gap A does not extend to the upper portion of the pre-DTI region 1911. This is to prevent a metal such as tungsten (W) to from penetrating into or entering the air gap A during a subsequent contact-forming process, which could result in deterioration of device characteristics.

When conventionally forming a trench for a DTI structure in a single process (e.g., without dividing the isolation region 191 into the pre-DTI region 1911 and the DTI region 1913 as in the present disclosure) and filling the trench, there is a technical limitation to the trench depth. That is, when the DTI region is formed by etching the substrate 101 in a single process, it is not easy to form the DTI region sufficiently deep so that adjacent devices are sufficiently electrically isolated.

In particular, when the substrate 101 is sufficiently thick to achieve a breakdown voltage (BV) of 100V or more, the corresponding DTI structure may not be sufficiently deep, which leads to problems that the breakdown voltage deteriorates due to an increase in the electric field area to the region below the DTI structure, and the leakage current may increase. In addition, in order to reduce or prevent transmission of noise between adjacent devices, the distance increases between adjacent devices, and thus the overall chip size increases.

FIG. 3 is a reference view showing the isolation characteristics according to the depth of the DTI region.

In order to prevent the above-described problem, in the semiconductor device 1 according to one or more embodiments of the present disclosure, the isolation region 191, particularly the DTI region 1913, is sufficiently deep as a result of forming the DTI region 1913 (having a relatively narrow width W2) by an additional etching process after forming the pre-DTI region 1911 (having a relatively large width W1). As previously described, it is preferable that the depth of the isolation region 191 is approximately 30 μm or more and 40 μm or less (e.g., from the uppermost surface of the substrate 101). Referring to FIG. 3, it can be seen that the isolation characteristics are improved by increasing the depth of the isolation region 191, achieved in two stages in the present disclosure.

Referring to FIG. 2, a dummy structure 193 may penetrate or pass through the dummy gate 173. The dummy structure 193 preferably comprises the same or substantially the same material as the isolation region 191 described above. In addition, the dummy structure 193 also penetrates or passes through the interlayer dielectric 180, and in some cases, at least partially overlaps the isolation layer 190 under the dummy gate 173. That is, the depth of the dummy structure 193 in the vertical direction may be variable or arbitrary. To be specific, the trench for the dummy structure 193 is formed during an etching process for the DTI region 1913 of the isolation region 191. At this time, when the dummy gate 173 is etched, the depth of the trench for the dummy structure 193 may be defined or determined according to the selectivity of etchant for the material of the dummy structure 193 (e.g., polysilicon) to the materials of the interlayer dielectric 180, the non-salicide region 175, and/or the isolation layer 190 (e.g., silicon dioxide and/or silicon nitride).

Generally, the pattern density for DTI structures is very low. As a result, problems such as poor deposition uniformity and over-etching in subsequent processes (such as deposition and etching of the interlayer dielectric 180) arise due to the low DTI pattern density and variations in the DTI pattern density across the device, resulting in process reliability degradation.

In order to prevent such problems, the semiconductor device according to one or more embodiments of the present disclosure seeks to improve the uniformity of structures made in subsequent processes by including (i) a dummy gate 173 and (ii) a dummy structure 193 penetrating or passing through the dummy gate 173 adjacent to the isolation region(s) that include a DTI region, so that the pattern density (e.g., of the gates and/or DTI regions across the device) is higher and/or more uniform.

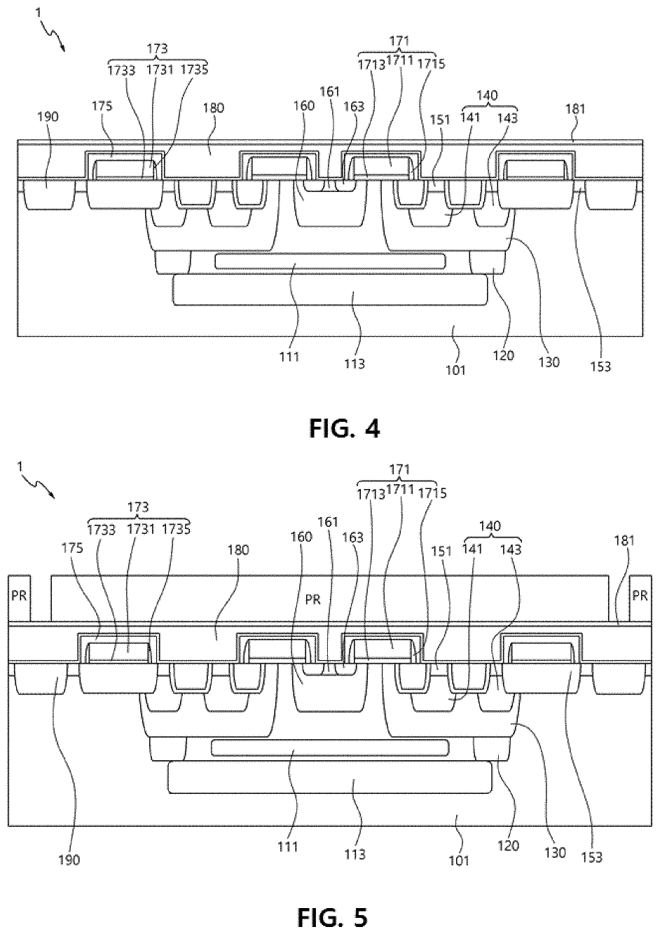

FIGS. 4 to 12 are cross-sectional views showing a method of manufacturing a semiconductor device according to one or more embodiments of the present disclosure.

Hereinafter, a method of manufacturing a semiconductor device according to one or more embodiments of the present disclosure will be described in detail with reference to the accompanying drawings. For convenience of description, descriptions of formation of wells, buried layers, the source, the drain, the gate and the dummy gate will be omitted, while the processes before, during and after formation of the isolation region 191 will be mainly described. The gate electrode 1711 and the dummy gate 173 may be formed by depositing and etching a film or layer comprising, for example, polysilicon on the substrate 101, and the non-salicide region 175 may be formed (e.g., by deposition and patterning of one or more insulator layers) on or over the dummy gates 173 and optionally the gates 171.

In the method of manufacturing a semiconductor device according to one or more embodiments of the present disclosure, first referring to FIG. 4, an interlayer dielectric 180 is formed on the substrate 101. For example, forming the interlayer dielectric 180 may comprise blanket-depositing a thin BPSG film or a PSG film (e.g., as a liner) on or over the dummy gates 173, the gates 171 and the substrate 101, and then depositing a IEOS film to a targeted thickness on the BPSG/PSG film. The TEOS film may then be planarized (e.g., by CMP) to provide it with a planar uppermost surface. Then, the etch stop layer 181 is blanket-deposited on the interlayer dielectric 180. The etch stop layer 181 functions as a polish stop layer in a subsequent CMP process, and may comprise, for example, a SiN layer.

Thereafter, the etch stop layer 181, the interlayer dielectric 180, and the isolation layer 190 are photolithographically patterned and etched to form a first trench 1911a corresponding to the pre-DTI region 1911. To be specific, referring to FIG. 5, for example, a first photoresist layer PR is patterned so expose areas of the etch stop layer 181 corresponding to the pre-DTI regions.

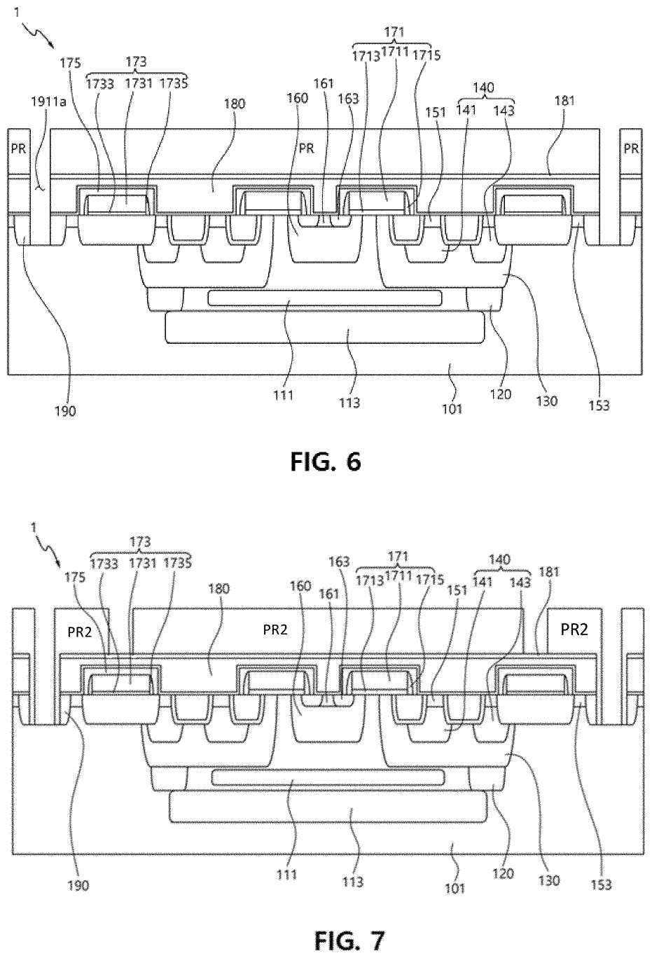

Thereafter, referring to FIG. 6, the first trench 1911a is formed by sequentially etching the etch stop layer 181, the interlayer dielectric 180, and the isolation layer 190. Then, the photoresist layer PR is removed by conventional stripping and cleaning.

Thereafter, referring to FIG. 7, a third trench 193a for the dummy structure 193 and the second trench 1913a connected to/under the first trench 1911a and for the DTI region 1913 are formed. To be specific, referring to FIG. 7, a second photoresist pattern PR2 is, for example, on the etch stop layer 181 and along the walls of the first trench 1911a. That is, the second photoresist layer PR2 includes an opening substantially equal to the maximum width of the second trench 1913a.

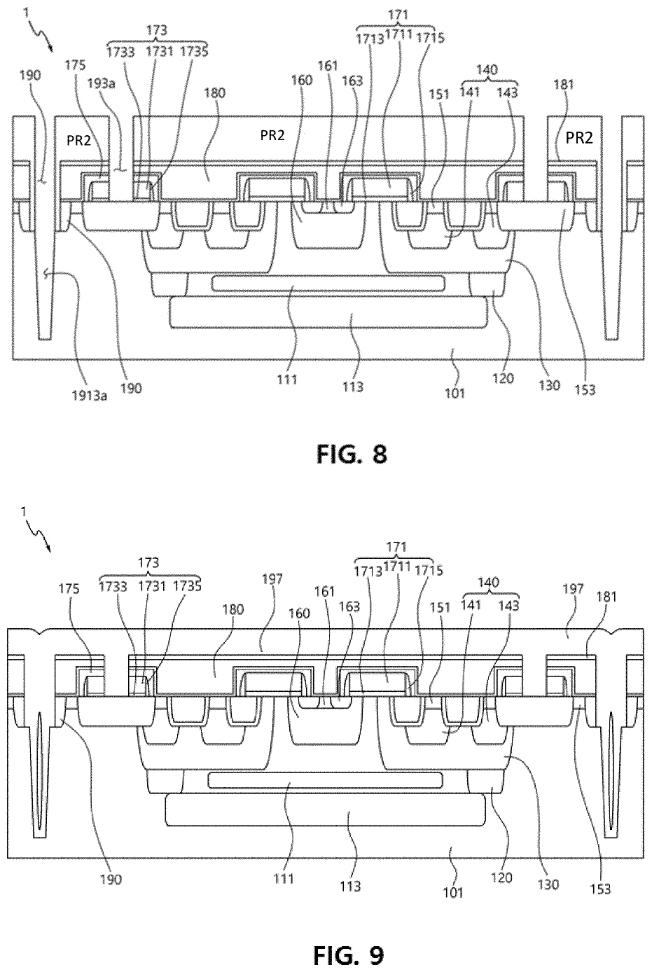

Thereafter, referring to FIG. 8, the substrate 101 below the first trench 1911a is etched to a depth of about 30-40 μm to form the second trench 1913a. At the same time, the third trench 193a for the dummy structure 193 may also be formed. As previously described, the depth of the third trench 193a may be defined or determined according to the selectivity of the etchant for doped or undoped silicon dioxide and/or silicon nitride to polysilicon (or vice versa), and the third trench 193a may extend into the isolation layer 190, or only partially pass through the dummy gate 173. It is preferable that the third trench 193a has a shallower depth than the second trench 1913a. Then, the second photoresist pattern PR2 is removed by stripping and cleaning.

Thereafter, referring to FIG. 9, a first insulating layer 197 is deposited (e.g., blanket-deposited or conformally deposited) on the etch stop layer 181 and in the first trench 1911a, the second trench 1913a, and the third trench 193a. The first insulating layer 197 may comprise a IEOS film, but the scope of the present disclosure is not limited thereto, and any silicon oxide film may be used. When performing this deposition process, the first insulating layer 197 is deposited on the etch stop layer 181. In addition, the first insulating layer 197 may fill the first trench 1911a, the second trench 1913a, and the third trench 193a.

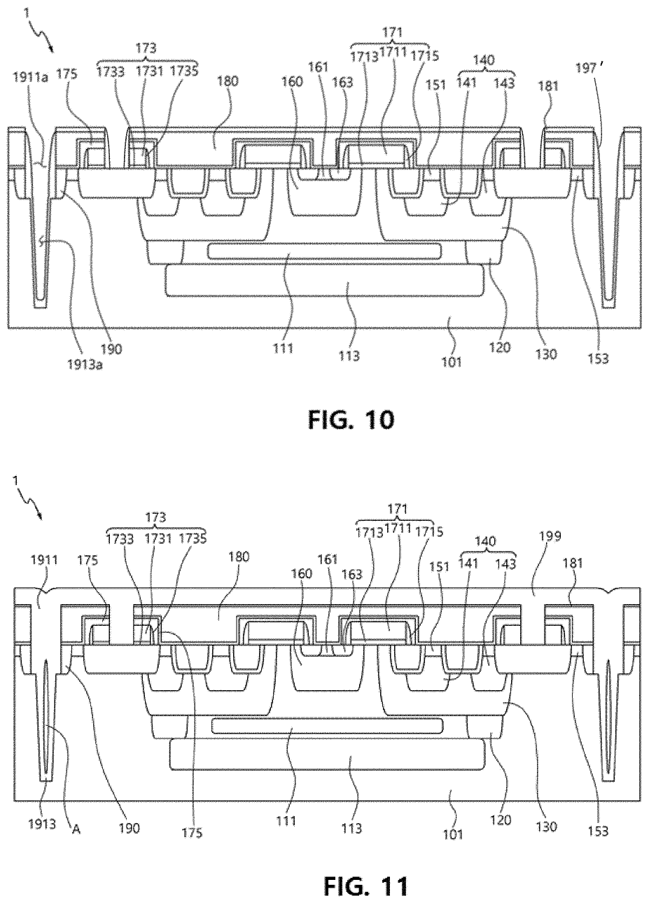

Thereafter, referring to FIG. 10, the first insulating layer 197 is etched (e.g., anisotropically or by an etch-back process). The first insulating layer 197 is substantially completely removed from the etch stop layer 181, and etching is performed until the first insulating layer 197 remains at or just below an uppermost edge of the etch stop layer 181, in the first trench 1911a. The etching also at least partially removes the first insulating layer 197 in the first trench 1911a and the second trench 1913a, to leave an insulating liner 197′ along the sidewalls of the first and second trenches 1911a-b. At the same time, the first insulating layer 197 in the third trench 193a is also partially removed to leave the insulating liner 197′ along the sidewalls of the third trench 193a. When the first insulating layer 197 is completely etched, the resulting structure is conventionally cleaned.

Thereafter, referring to FIG. 11, a second insulating layer 199 is deposited on the etch stop layer 181 and inside the first trench 1911a, the second trench 1913a, and the third trench 193a. The second insulating layer 199 may also be deposited on the insulating liner 197′ inside the first trench 1911a, the second trench 1913a, and the third trench 193a. An air gap A may be formed in the second insulating layer 199 in the second trench 1913a (and sometimes partially in the first trench 1911a). The air gap A may further prevent transmission of noise between adjacent devices (e.g., on opposite sides of the second trench 1913a), thereby making the devices more electrically stable.

It is preferable that the air gap A has an uppermost end or surface below the interlayer dielectric 180 (or an uppermost surface thereof), and has an appropriate height or depth to prevent penetration or entry of tungsten (W) or the like into the air gap A during subsequent processing. The pre-DTI structure 1911 and the DTI structure 1913 are completed by this process. The second insulating layer 199 may comprise the same material as the first insulating layer 197, although there is no limitation thereto. For example, any silicon oxide (e.g., undoped silicon dioxide, or silicon dioxide doped with [i] boron and/or phosphorous or [ii] fluorine) may be used.

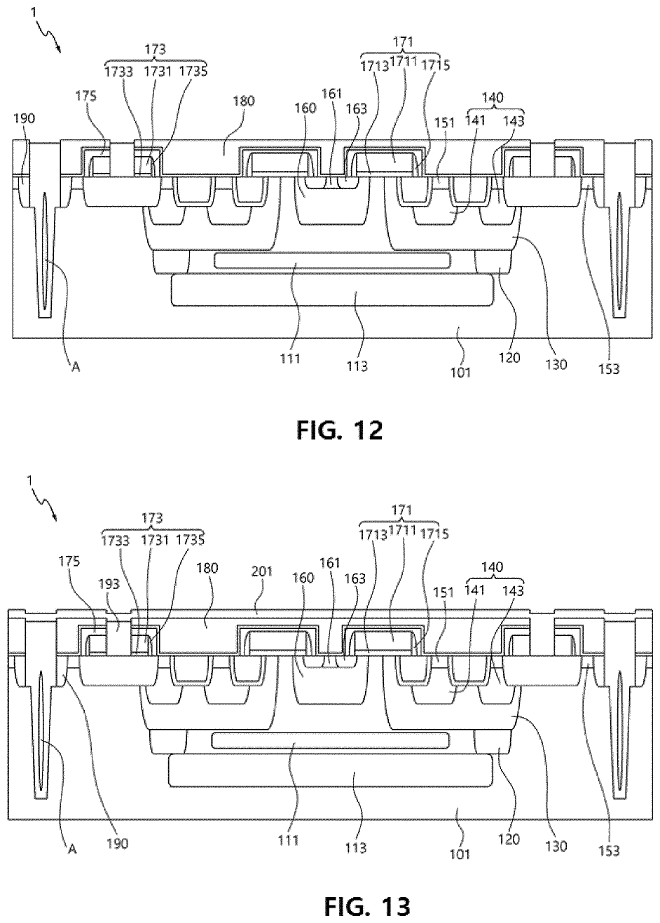

Thereafter, referring to FIG. 12, the second insulating layer 199 on or above the etch stop layer 181 may be removed by planarization (e.g., CMP). That is, the second insulating layer 199 on the etch stop layer 181 is removed by CMP using the etch stop layer 181 as a polish stop layer. Then, the etch stop layer 181 is removed by etching (e.g., selective wet etching), and the resulting structure shown in FIG. 12 is conventionally cleaned.

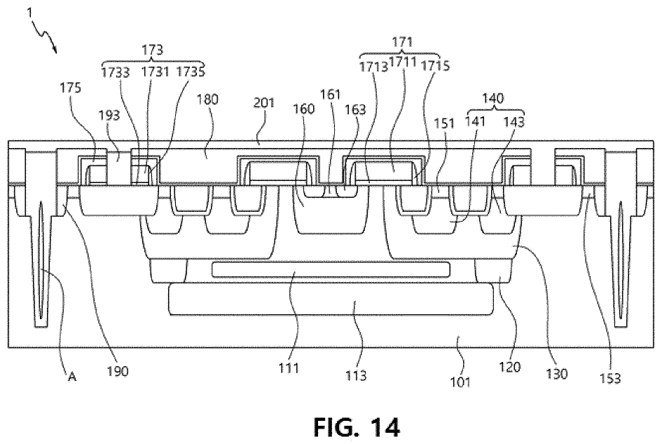

FIGS. 13 and 14 are cross-sectional views showing a process of removing a step that may be formed at the boundary between the isolation region 190 and the interlayer dielectric 180.

Referring to FIG. 13, the etch stop layer 181 is removed (e.g., by etching) while the uppermost surface of the pre-DTI region 1911 is exposed. In the process of etching the etch stop layer 181, the pre-DTI region 1911 may also be partially etched. That is, oxide loss may occur from the pre-DTI region 1911. Thereby, a step may be created between the isolation region 191 and the interlayer dielectric 180 adjacent thereto. Alternatively, the pre-DTI 1911 may have an uppermost surface that is substantially coplanar with the uppermost surface of the etch stop layer 181, and the exposed surface of the pre-DTI region 1911 may not be etched significantly during selective etching of the etch stop layer 181. In a subsequent contact-forming process, a contact-forming material such as tungsten (W) may remain on the upper surface of the pre-DTI region 1911, resulting in deterioration of characteristics of the isolation region 191.

The process described below is for removing the step height, but it should be noted that such process is not an essential step of the present disclosure.

In order to solve the above-mentioned problem, referring to FIG. 14, a third insulating layer 201 is deposited on the interlayer dielectric 180 and on the isolation region 191. The third insulating layer 201 may comprise a silicon dioxide layer formed from a ILOS or silane (SiH₄) precursor, but is not limited thereto. Then, the third insulating layer 201 is planarized (e.g., by CMP). By depositing the third insulating layer 201 on the exposed isolation region 191, it is possible to prevent the upper part of the isolation region 191 from being opened during subsequent processing, and planarizing the third insulating layer 201 removes the step height at the same time. The breakdown voltage characteristics (e.g., of the DMOS transistor) may be improved by removing the step height.

The above detailed description is illustrative of the present disclosure. In addition, the above description shows and describes various embodiments ofthe present disclosure, and the present disclosure can be used in various other combinations, modifications, and environments. In other words, changes or modifications are possible within the scope of the concept of the disclosure disclosed herein, the scope equivalent to the written disclosure, and/or within the scope of skill or knowledge in the art. The above-described embodiments describe various manners and/or states for implementing the technical idea of the present disclosure, and various changes for specific application fields and/or uses of the present disclosure are possible. Accordingly, the detailed description of the present disclosure is not intended to limit the present disclosure to the disclosed embodiments.

What is claimed is:

1. A semiconductor device, comprising:
a substrate;
a gate on the substrate;
a dummy gate on the substrate;
an interlayer dielectric on the substrate;
an isolation layer in the substrate;
an isolation region passing through the interlayer dielectric and the isolation layer, and penetrating into the substrate; and
a dummy structure passing through the interlayer dielectric and extending to and/or passing through the dummy gate.

2. The semiconductor device of claim 1, wherein the isolation region has a lowermost surface deeper than a lowermost surface of the dummy structure.

3. The semiconductor device of claim 1, wherein the isolation region comprises:
a pre-DTI region passing through the interlayer dielectric and extending at least partially through the first isolation layer; and
a DTI region connected to the pre-DTI region and extending a predetermined distance into the substrate, and having a width smaller than that of the pre-DTI region.

4. The semiconductor device of claim 1, wherein the dummy structure has a lowermost surface that is below a lowermost surface of the dummy gate.

5. The semiconductor device of claim 1, further comprising:
an air gap in the isolation region.

6. A semiconductor device, comprising:
a substrate;
a first buried layer having a second conductivity type in the substrate;
a deep well directly or indirectly connected to the first buried layer;
a first well in the deep well;
a drain in the first well and at a surface of the substrate;
a body region having a first conductivity type in the substrate;
a source in the body region and at the surface of the substrate;
a gate on the substrate;
a dummy gate on the substrate;
an interlayer dielectric covering the gate;
an isolation layer in the substrate;
an isolation region extending into the substrate through the isolation layer;
a dummy structure extending at least partially through the dummy gate; and
an air gap in the isolation region.

7. The semiconductor device of claim 6, wherein the isolation region and the dummy structure penetrate or pass through the interlayer dielectric.

8. The semiconductor device of claim 6, further comprising:
a high-voltage well having the second conductivity type, connected to the first buried layer and a deep well in the substrate; and
a second buried layer having the first conductivity type in the substrate.

9. The semiconductor device of claim 6, wherein the isolation region comprises:
a pre-DTI region passing through the interlayer dielectric and extending at least partially through the isolation layer; and
a DTI region connected to the pre-DTI region and extending a predetermined distance into the substrate, and having a width smaller than that of the pre-DTI region,
wherein the air gap has an uppermost end or surface in or below the DTI region.

10. The semiconductor device of claim 6, further comprising:
a non-salicide structure on the dummy gate.

11. A method of manufacturing a semiconductor device, the method comprising:
forming an isolation layer in a substrate;
forming a gate on the substrate;
forming a dummy gate on the substrate;
depositing an interlayer dielectric on the substrate;
forming a first trench by etching the interlayer dielectric and the isolation layer;
forming a second trench by etching the substrate under the isolation layer or exposed by the first trench;
forming a third trench by etching the interlayer dielectric and the dummy gate; and
filling the first trench, the second trench, and the third trench with an insulating layer to form an isolation region and a dummy structure.

12. The method of manufacturing a semiconductor device of claim 11, wherein the second trench and the third trench are formed in a single process, and
the second trench has a lowermost surface that is below a lowermost surface of the third trench.

13. The method of manufacturing a semiconductor device of claim 11, further comprising:
depositing an etch stop layer on the interlayer dielectric,
wherein forming the isolation region and a dummy structure comprises:
depositing a first insulating layer in the first trench and the second trench;
removing the first insulating layer on the etch stop layer and at least partially from the second trench; and
depositing a second insulating layer in the first trench, the second trench, and the third trench.

14. The method of manufacturing a semiconductor device of claim 13, further comprising:
removing the etch stop layer;
depositing a third insulating layer on the interlayer dielectric and the isolation region; and
to planarizing the third insulating layer.

15. The method of manufacturing a semiconductor device of claim 13, wherein forming the first trench comprises:
forming a first photoresist pattern having an opening exposing the etch stop layer; and
etching the etch stop layer, the interlayer dielectric, and the isolation region.

16. The method of manufacturing a semiconductor device of claim 15, wherein forming the second trench comprises:
forming a second photoresist pattern on the etch stop layer and along sidewalls of the first trench; and
etching the substrate under or exposed by the first trench.

17. A method of manufacturing a semiconductor device, the method comprising:
forming an isolation layer in a substrate;
forming a gate on the substrate;
forming a dummy gate on the substrate;
depositing an interlayer dielectic on the substrate;
forming a pre-DTI region extending at least partially through the isolation layer;
forming a DTI region extending below the pre-DTI region, including an air gap and having a width smaller than that of the pre-DTI region; and
forming a dummy structure extending at least partially through the dummy gate.

18. The method of manufacturing a semiconductor device of claim 17, further comprising:
forming a non-salicide structure on the dummy gate.

19. The method of manufacturing a semiconductor device of claim 17, wherein forming the pre-DTI region and forming the DTI region comprise two or more insulating layer depositions and etching processes.
